(19) United States
(12) Patent Application Publication
(10) Pub. No.: US 2026/0282212 A1
(43) Pub. Date: Sep. 17, 2026

(54) INTERCONNECT SUBSTRATE AND METHOD OF MAKING SAME

(71) Applicant: SHINKO ELECTRIC INDUSTRIES CO., LTD., Nagano (JP)

(72) Inventors: Jun YOSHIIKE, Nagano (JP); Masahiro SUNOHARA, Nagano (JP); Noriyoshi SHIMIZU, Nagano (JP)

(21) Appl. No.: 19/552,262

(22) Filed: Feb. 27, 2026

(30) Foreign Application Priority Data
Mar. 11, 2025 (JP) 2025-038142

(51) Int. Cl. H05K 1/02; H05K 1/03; H05K 3/00

(52) U.S. Cl. CPC H05K 1/0271; H05K 1/0306; H05K 3/0029; H05K 2201/068; H05K 2201/09136; H05K 2203/107

(57) ABSTRACT

An interconnect substrate includes a core layer made of glass having one surface, another surface opposite the one surface, and a first cut-out located on an outer side of the one surface, a first buffer layer filling the first cut-out, and a first insulating layer disposed on the one surface of the core layer and covering the first buffer layer, wherein the first buffer layer has a lower elastic modulus than the first insulating layer.

### CROSS-REFERENCE TO RELATED APPLICATIONS

The present application is based on and claims priority to Japanese Patent Application No. 2025-038142 filed on Mar. 11, 2025, with the Japan Patent Office, the entire contents of which are incorporated herein by reference.

### FIELD

The disclosures herein generally relate to interconnect substrates and methods of making an interconnect substrate.

### BACKGROUND

Interconnect substrates known in the art may each include interconnect layers and insulating layers laminated on the upper surface of a core layer. In such an interconnect substrate, a cut-out may be provided in the periphery of the core layer. The cut-out is coated with a resin. Further, the resin extends from the inside of the cut-out beyond the upper surface of the core layer and covers the side surface of an insulating layer (Patent Document 1).

A glass core layer may sometimes be used in an interconnect substrate. Since the thermal expansion coefficient of the glass core layer is significantly different from that of the resin constituting the insulating layers, internal fractures may develop in the glass due to the thermal contraction force caused by the difference in the thermal expansion coefficients.

### RELATED-ART DOCUMENT

### Patent Document

Patent Document 1 Japanese Patent No. 5297139

### SUMMARY

According to an aspect of the embodiment, an interconnect substrate includes a core layer made of glass having one surface, another surface opposite the one surface, and a first cut-out located on an outer side of the one surface, a first buffer layer filling the first cut-out, and a first insulating layer disposed on the one surface of the core layer and covering the first buffer layer, wherein the first buffer layer has a lower elastic modulus than the first insulating layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of an interconnect substrate according to a first embodiment;

FIG. 2 is a drawing illustrating an example of a manufacturing process of the interconnect substrate according to the first embodiment;

FIGS. 3A through 3D are drawings illustrating the example of the manufacturing process of the interconnect substrate according to the first embodiment;

FIGS. 4A through 4C are drawings illustrating the example of the manufacturing process of the interconnect substrate according to the first embodiment;

FIGS. 5A through 5D are drawings illustrating the example of the manufacturing process of the interconnect substrate according to the first embodiment;

FIG. 6 is a plan view illustrating an example of an interconnect substrate according to a first variation of the first embodiment; and

FIG. 7 is a plan view illustrating an example of an interconnect substrate according to the second variation of the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate of First Embodiment

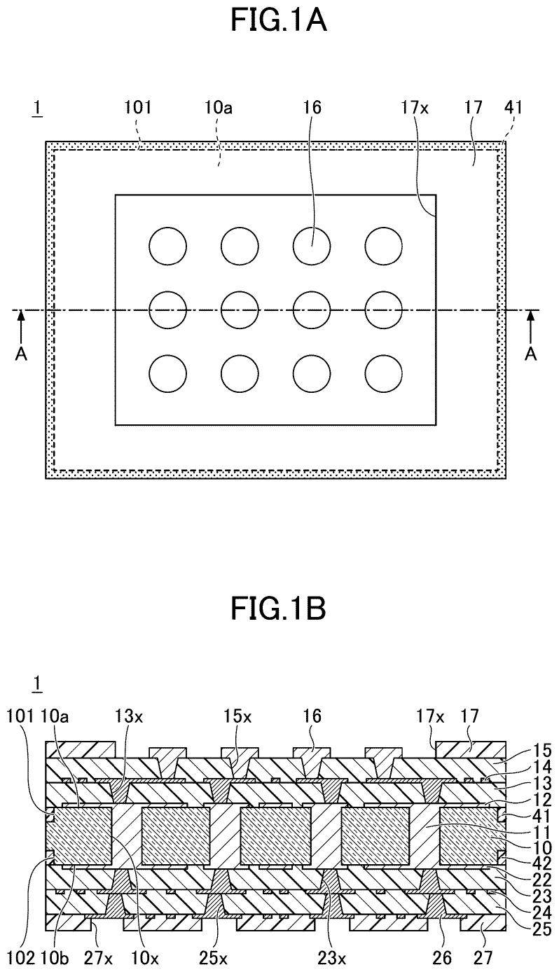

FIGS. 1A and 1B are drawings illustrating an example of an interconnect substrate according to a first embodiment. FIG. 1A is a plan view and FIG. 1B is a cross-sectional view taken along line A-A in FIG. 1A.

Referring to FIG. 1, the interconnect substrate 1 is configured such that a core layer 10 includes a first surface 10a and a second surface 10b opposite the first surface 10a, and interconnect layers and insulating layers are laminated on the first surface 10a and the second surface 10b of the core layer 10.

Specifically, the interconnect substrate 1 includes an interconnect layer 12, an insulating layer 13, an interconnect layer 14, an insulating layer 15, an interconnect layer 16, and a solder resist layer 17 sequentially laminated on the first surface 10a of the core layer 10. On the second surface 10b of the core layer 10, an interconnect layer 22, an insulating layer 23, an interconnect layer 24, an insulating layer 25, an interconnect layer 26, and a solder resist layer 27 are sequentially laminated.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x extending through the core layer 10 in the thickness direction. The plan shape of each through hole 10x is, for example, circular.

The core layer 10 has a first cut-out 101 located on the outer side of the first surface 10a. The core layer 10 has a second cut-out 102 located on the outer side of the second surface 10b. In the directions perpendicular to the side surfaces of the core layer 10, the width of the first cut-out 101 and the width of the second cut-out 102 may each be, for example, in the range of approximately 0.05 mm to 0.5 mm. In the direction parallel to the side surfaces of the core layer 10, the depth of the first cut-out 101 and the depth of the second cut-out 102 may each be, for example, in the range of approximately 0.05 mm to 0.3 mm.

In plan view, the first surface 10a of the core layer 10 has a plurality of corners, and the first cut-out 101 includes at least a portion bent along the perimeter of each corner of the first surface 10a. In plan view, the second surface 10b of the core layer 10 has a plurality of corners, and the second cut-out 102 includes at least a portion bent along the perimeter of each corner of the second surface 10b.

In the example illustrated in FIGS. 1A and 1B, the first surface 10a and the second surface 10b of the core layer 10 are square or rectangular, and each surface has four corners. In the example illustrated in FIGS. 1A and 1B, in plan view, the first cut-out 101 includes portions bent along the perimeters of the four corners of the first surface 10a, and is formed along the perimeter of the first surface 10a in a closed-loop shape. The second cut-out 102 includes portions bent along the four corners of the second surface 10b, and is formed along the perimeter of the second surface 10b in a closed-loop shape.

In each of the first cut-out 101 and the second cut-out 102, the connection portion between the side portion and the bottom portion may be bent so as to form a corner, or may be curved without forming a corner. For example, the connection portion between the side portion and the bottom portion may be bent at substantially a right angle in cross-sectional view, or may be curved in an arc shape or an elliptical arc shape in cross-sectional view. The side portion may or may not be perpendicular to the first surface 10a and the second surface 10b of the core layer 10.

The side portion of the first cut-out 101 connects to the first surface 10a and extends from the first surface 10a toward the second surface 10b. The bottom portion connects to the lateral surface of the core layer 10 and extends from the lateral surface toward the through holes 10x. In the first cut-out 101, the boundaries between the side portion, the bottom portion, and the connection portion need not be clear.

The side portion of the second cut-out 102 connects to the second surface 10b and extends from the second surface 10b toward the first surface 10a. The bottom portion connects to the lateral surface of the core layer 10 and extends from the lateral surface toward the through holes 10x. In the second cut-out 102, the boundaries between the side portion, the bottom portion, and the connection portion need not be clear.

The interconnect substrate 1 includes a first buffer layer 41 and a second buffer layer 42. The first buffer layer 41 fills the first cut-out 101. The upper surface of the first buffer layer 41 is flush with the first surface 10a of the core layer 10, for example. The side surface of the first buffer layer 41 is flush with the side surface of the core layer 10, for example. The side surface of the first buffer layer 41 is flush with the side surfaces of the insulating layers and the solder resist layer 17 stacked on the first surface 10a of the core layer 10, for example.

The second buffer layer 42 fills the second cut-out 102. The lower surface of the second buffer layer 42 is flush with the second surface 10b of the core layer 10, for example. The side surface of the second buffer layer 42 is flush with the side surface of the core layer 10, for example. The side surface of the second buffer layer 42 is flush with the side surfaces of the insulating layers stacked on the second surface 10b of the core layer 10 and the side surface of the solder resist layer 27, for example.

The material of the first buffer layer 41 and the second buffer layer 42 may be, for example, an insulating resin mainly consisting of an epoxy-based resin or a polyimide-based resin. The first buffer layer 41 and the second buffer layer 42 may contain a filler such as silica (SiO₂). As an alternative configuration, the first buffer layer 41 and the second buffer layer 42 may not contain a filler.

The interconnect layer 12 is disposed on the first surface 10a of the core layer 10. The interconnect layer 22 is disposed on the second surface 10b of the core layer 10. The interconnect layer 12 and the interconnect layer 22 are electrically connected by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu) or the like. The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12 and the first buffer layer 41. The insulating layer 13 continuously covers the upper surface of the first buffer layer 41 and the first surface 10a of the core layer 10. The material of the insulating layer 13 may be, for example, an insulating resin or the like mainly composed of an epoxy-based resin or a polyimide-based resin. The thickness of the insulating layer 13 may be, for example, in the range of approximately 20 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thicknesses of the pads may alternatively be greater than that of the interconnect layer 12. The interconnect layer 16 may also include an interconnect pattern in addition to the pads.

The solder resist layer 17 is a protective insulating layer located as the outermost layer on the first side of the interconnect substrate 1, and is formed on the upper surface of the insulating layer 15 while leaving the interconnect layer 16 exposed. The solder resist layer 17 may be formed in a closed-loop configuration to leave the interconnect layer 16 exposed in an opening 17x, for example. The pads of the interconnect layer 16 exposed in the opening 17x may be used for electrical connections with an electronic component such as a semiconductor chip, for example. The solder resist layer 17 may be formed of, for example, a photosensitive epoxy-based insulating resin or acrylic-based insulating resin. The thickness of the solder resist layer 17 is, for example, in the range of approximately 15 to 35 μm.

On the surface of the interconnect layer 16 exposed in the opening 17x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

The insulating layer 23 is an interlayer insulating layer disposed on the second surface 10b of the core layer 10 and covering the interconnect layer 22 and the second buffer layer 42. The insulating layer 23 continuously covers the lower surface of the second buffer layer 42 and the second surface 10b of the core layer 10. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 via the via interconnects. The material and thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 via the via interconnects. The material and the thickness of the interconnect layer 26 may be substantially the same as those of the interconnect layer 12, for example.

The solder resist layer 27 is a protective insulating layer located as the outermost layer on the second side of the interconnect substrate 1, and is formed on the lower surface of the insulating layer 25 to cover the interconnect layer 26. The material and the thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

The first buffer layer 41 has a lower elastic modulus than the insulating layer 13. The second buffer layer 42 has a lower elastic modulus than the insulating layer 23. That is, the first buffer layer 41 and the second buffer layer 42 are softer and more extensible than the insulating layers 13 and 23. The elastic moduli of the first buffer layer 41 and the second buffer layer 42 are, for example, from 2 GPa to 8 GPa. The elastic moduli of the insulating layers 13 and 23 are, for example, from 10 GPa to 15 GPa. The elastic modulus of the core layer 10 is higher than the elastic moduli of the first and second buffer layers 41 and 42 and the insulating layers 13 and 23, and is, for example, from 70 GPa to 80 GPa. The elastic modulus as used in this application refers to a tensile elastic modulus at 25° C. The elastic modulus may be measured by a method in accordance with JIS K7161.

The first buffer layer 41 has a higher coefficient of thermal expansion than the insulating layer 13. The second buffer layer 42 has a higher coefficient of thermal expansion than the insulating layer 23. The coefficients of thermal expansion of the first buffer layer 41 and the second buffer layer 42 are, for example, from 20 ppm/° C. to 110 ppm/° C. The coefficients of thermal expansion of the insulating layers 13 and 23 are, for example, from 10 ppm/° C. to 20 ppm/° C. The coefficient of thermal expansion of the core layer 10 is lower than the coefficients of thermal expansion of the first and second buffer layers 41 and 42 and the insulating layers 13 and 23, and is, for example, from 3 ppm/° C. to 10 ppm/° C.

When the same resin is used, the elastic modulus and the coefficient of thermal expansion may be controlled by varying the filler content. As the filler content increases, the elastic modulus tends to increase and the coefficient of thermal expansion tends to decrease. The elastic modulus and the coefficient of thermal expansion may be adjusted by selecting different resins. The elastic modulus and the coefficient of thermal expansion may be controlled by selecting different resins and further varying the filler content.

### Method of Making Interconnect Substrate

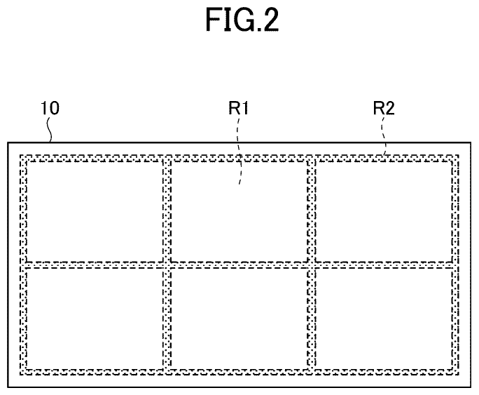

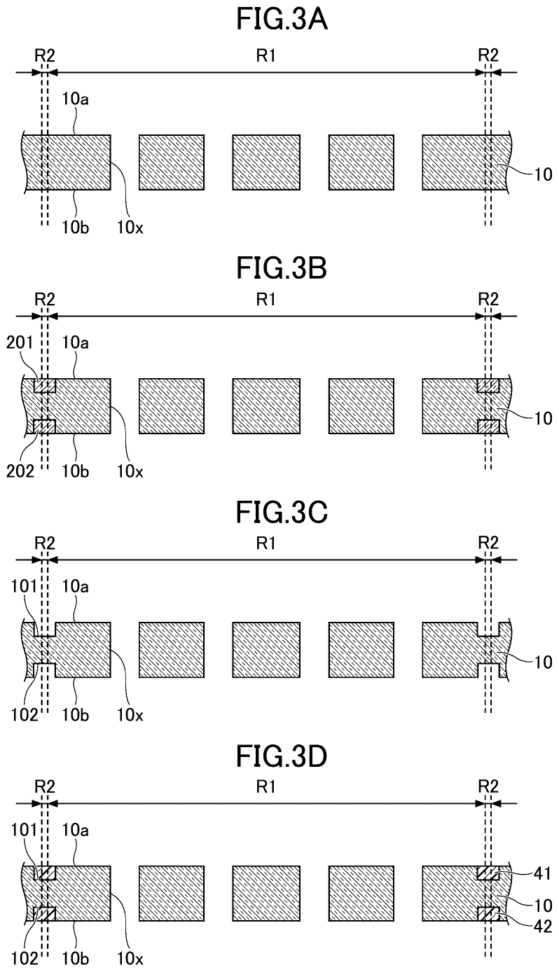

FIG. 2 to FIGS. 5A through 5D are drawings illustrating an example of a manufacturing process of the interconnect substrate according to the first embodiment. FIG. 2 is a plan view, and FIGS. 3A through 3D to FIGS. 5A through 5D are cross-sectional views.

First, in the step illustrated in FIG. 2, a glass core layer 10 is prepared. The core layer 10 includes a plurality of interconnect regions R1 that are to be singulated to form interconnect substrates, and a cutting region R2 along which a cut is made for singulation. FIG. 2 depicts the cutting region R2 in dot shading for convenience.

In the step illustrated in FIG. 3A, through holes 10x are formed in each interconnect region R1 of the core layer 10 by wet etching. Examples of the etching solution include hydrofluoric acid, a strong alkaline solution, and the like.

In the step illustrated in FIG. 3B, a first modified layer 201 having a width wider than the cutting region R2 is formed by laser irradiation so as to extend along, and encompass, the cutting region R2 in the first surface 10a of the core layer 10. Further, a second modified layer 202 having a width wider than the cutting region R2 is formed by laser irradiation so as to extend along, and encompass, the cutting region R2 in the second surface 10b of the core layer 10. The first modified layer 201 and the second modified layer 202 may be formed so as to be aligned with each other in plan view. The widths and depths of the first modified layer 201 and the second modified layer 202 may be controllable, for example, by adjusting the irradiation power and the irradiation time of the laser light. The term “modified layer” refers to a portion in which the mechanical strength and other physical characteristics are different from those of the surroundings. The modified layer has a lower mechanical strength than the other portions of the core layer 10.

In plan view, the interconnect region R1 on the first surface 10a of the core layer 10 has a plurality of corners, and the first modified layer 201 includes at least a portion bent along each corner of the interconnect region R1 on the first surface 10a. The first modified layer 201 may be provided along the entire periphery of the interconnect region R1 on the first surface 10a. In plan view, the interconnect region R1 on the second surface 10b of the core layer 10 has a plurality of corners, and the second modified layer 202 includes at least a portion bent along each corner of the interconnect region R1 on the second surface 10b. The second modified layer 202 may be provided along the entire periphery of the interconnect region R1 of the second surface 10b.

In the step illustrated in FIG. 3C, the first modified layer 201 is removed by wet etching to form a first cut-out 101, and the second modified layer 202 is removed by wet etching to form a second cut-out 102. The first cut-out 101 is formed so as to be wider than the cut region R2 and to extend along, and encompass, the cutting region R2 on the first surface 10a of the core layer 10. The second cut-out 102 is formed so as to be wider than the cut region R2 and to extend along, and encompass, the cutting region R2 on the second surface 10b of the core layer 10. Examples of the etching solution include hydrofluoric acid, a strong alkaline solution, and the like. The first modified layer 201 and the second modified layer 202 each have an etching rate higher than that of the other portions of the core layer 10, and are thus selectively etched and removed.

In the step illustrated in FIG. 3D, a first buffer layer 41 is formed to fill the first cut-out 101 and a second buffer layer 42 is formed to fill the second cut-out 102. For example, a semi-cured epoxy-based resin film or the like is laminated on each interconnect region R1 and the cutting region R2 on the first surface 10a of the core layer 10 so as to cover the first cut-out 101 and cured. In so doing, the first cut-out 101 is filled with the semi-cured epoxy-based resin film. Thereafter, the resin formed on the first surface 10a of the core layer 10 is removed by a polishing process such as a CMP method. This process effectively forms the first buffer layer 41 that fills the first cut-out 101. The second buffer layer 42 filling the second cut-out 102 may also be formed in substantially the same manner. The upper surface of the first buffer layer 41 and the first surface 10a of the core layer 10 are flush, for example. The lower surface of the second buffer layer 42 and the second surface 10b of the core layer 10 are flush, for example. It may be noted that, instead of laminating the epoxy-based resin film or the like, an epoxy-based resin or the like in liquid or paste form is applied and then cured to form the first buffer layer 41 and the second buffer layer 42. A photosensitive insulating material may also be used as the resin material.

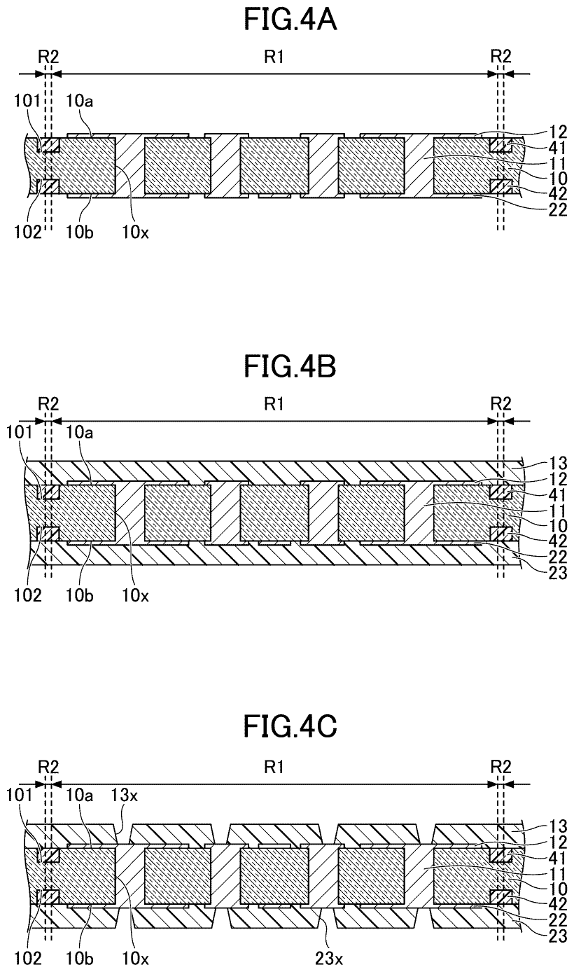

In the step illustrated in FIG. 4A, an interconnect layer 12 is disposed in each interconnect region R1 on the first surface 10a of the core layer 10, and an interconnect layer 22 is disposed in each interconnect region R1 on the second surface of the core layer 10, with through interconnects 11 formed in the through holes 10x. For example, a seed layer (copper or the like) covering the first surface 10a, the second surface 10b, and the inner wall surfaces of the through holes 10x of the core layer 10 is formed by electroless plating, sputtering, or the like, followed by forming an electrolytic plating layer (copper or the like) on the seed layer by electrolytic plating using the seed layer as a path to feed current. This arrangement fills the through holes 10x with the electrolytic plating layer formed on the seed layer, and forms the interconnect layers 12 and 22 each as a laminate of the seed layer and the electrolytic plating layer on the first surface 10a and the second surface 10b, respectively, of the core layer 10. Thereafter, the interconnect layers 12 and 22 are each patterned into a predetermined plan shape by a subtractive method or the like.

In the step illustrated in FIG. 4B, an insulating layer 13 covering the interconnect layer 12 and the first buffer layer 41 is disposed in each interconnect region R1 and the cutting region R2 on the first surface 10a of the core layer 10. Specifically, for example, a semi-cured epoxy-based resin film or the like is laminated on the first surface 10a of the core layer 10 so as to cover the interconnect layer 12 and the first buffer layer 41, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, an insulating layer 23 covering the interconnect layer 22 and the second buffer layer 42 is disposed in each interconnect region R1 and the cutting region R2 on the second surface 10b of the core layer 10.

In the step illustrated in FIG. 4C, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed by, for example, laser processing using a CO₂ laser or the like. After the via holes 13x and 23x are formed, desmearing is preferably performed to remove resin residues adhering to the surfaces of the interconnect layers 12 and 22 exposed at the end of the via holes 13x and 23x.

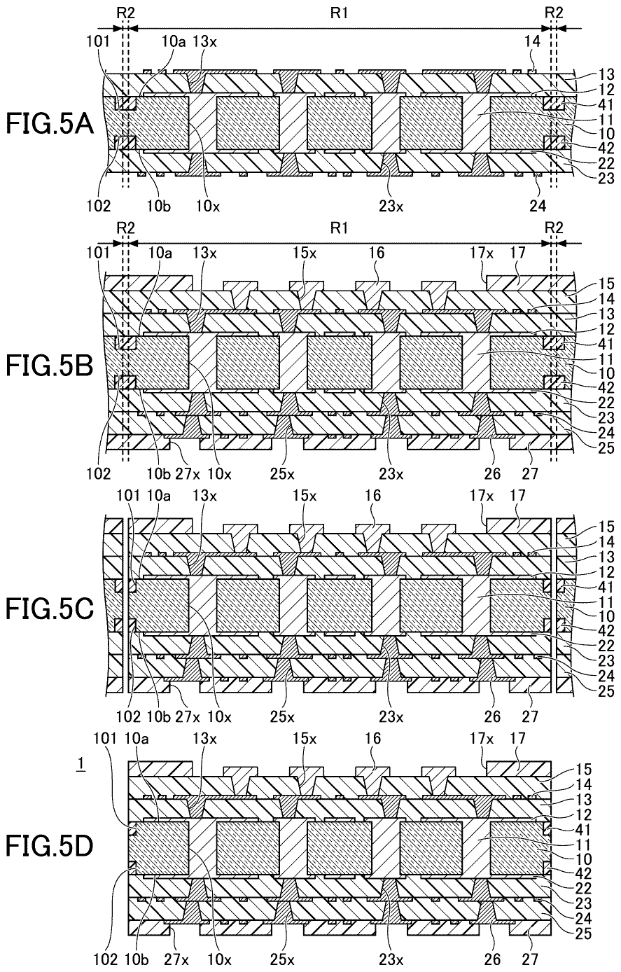

In the step illustrated in FIG. 5A, an interconnect layer 14 is formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, an interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example.

In the step illustrated in FIG. 5B, first, substantially the same steps as those in FIGS. 4B to 4D are repeated to form insulating layers 15 and 25 and interconnect layers 16 and 26. Next, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that for forming the solder resist layer 17. Thereafter, the solder resist layers 17 and 27 are exposed and developed. As a result, an opening 17x is formed through the solder resist layer 17 to expose the interconnect layer 16. Also, openings 27x for exposing portions of the lower surface of the interconnect layer 26 are formed in the solder resist layer 27.

In the step illustrated in FIG. 5C, the structure illustrated in FIG. 5B is cut along the cutting region R2 for singulation. As a result, a plurality of interconnect substrates 1, each of which is the same as the one illustrated in FIG. 5D, are formed. The cutting may be performed by, for example, a dicing blade. By the cutting, the first buffer layer 41 and the second buffer layer 42 are divided, and the side surfaces of the divided first buffer layer 41 and the divided second buffer layer 42 are exposed at the side surface of each singulated structure. The side surfaces of the first buffer layer 41 and the second buffer layer 42 are flush with the side surface of each layer of the singulated structure, for example. The cutting may be performed by laser irradiation or the like. By following these steps, the manufacture of the interconnect substrate 1 is achieved.

Generally, an interconnect substrate is such that the glass core layer, the interconnect layers, and the insulating layers have different coefficients of thermal expansion. For example, the thermal expansion coefficient of a glass core layer is in the range of approximately 3 to 15 ppm/° C., and the thermal expansion coefficient of interconnect layers made of copper is about 17 ppm/° C. The thermal expansion coefficient of insulating layers made of resin is in the range of approximately 10 to 100 ppm/° C. As a result, an increase in the temperature of the interconnect substrate due to heating generates thermal contraction force at the center region of the interconnect substrate, causing tensile stress in the vertical direction and the concentration of the stress at the periphery of the glass core layer. The strength of the glass may be insufficient, and internal fracture may occur, originating at the periphery.

The most likely originating points are the interface between the core layer 10 and the insulating layer 13, and the interface between the core layer 10 and the insulating layer 23. In consideration of this, the first buffer layer 41 is provided near the interface between the core layer 10 and the insulating layer 13, and the second buffer layer 42 is provided near the interface between the core layer 10 and the insulating layer 23. This arrangement effectively mitigates the mismatch of the thermal expansion coefficients between the core layer 10 made of glass and the insulating layers 13 and 23. As a result, the internal fracture of the glass constituting the core layer 10 is effectively suppressed.

The first buffer layer 41 need not be provided on the first surface 10a of the core layer 10, and the second buffer layer 42 need not be provided on the second surface 10b of the core layer 10. That is, the provision of the insulating layer having a high elastic modulus on each of the first surface 10a and the second surface 10b of the core layer 10 without a highly extensible buffer layer allows a highly reliable laminate structure to be formed on each of the first surface 10a and the second surface 10b of the core layer 10. When the step illustrated in FIG. 3D is performed to remove the resin formed on the first surface 10a of the core layer 10 by polishing such as CMP, an ultra-thin buffer layer may be left to cover the first surface 10a. Further, when polishing such as CMP is performed to remove the resin formed on the second surface 10b of the core layer 10, an ultra-thin buffer layer may be left to cover the second surface 10b. Here, the ultra-thin film thickness refers to a film thickness smaller than those of the interconnect layers 12 and 22, and is, for example, 5 μm or less. Even when such a thin buffer layer remains on each of the first surface 10a and the second surface 10b, a highly reliable laminate structure similar to the one described above is successfully formed.

Further, even if a microcrack occurs in the vicinity of the side surface of the core layer 10 during the singulation in the step illustrated in FIG. 5C, the presence of the first buffer layer 41 and the second buffer layer 42 effectively suppresses internal fracturing of the glass constituting the core layer 10.

### Variations of First Embodiment

Variations of the first embodiment are directed to examples in which the positions of the first cut-out 101 and the second cut-out 102 are different from those in the interconnect substrate of the first embodiment. In connection with the variations of the first embodiment, descriptions of the same components as those of the already described embodiment may be omitted.

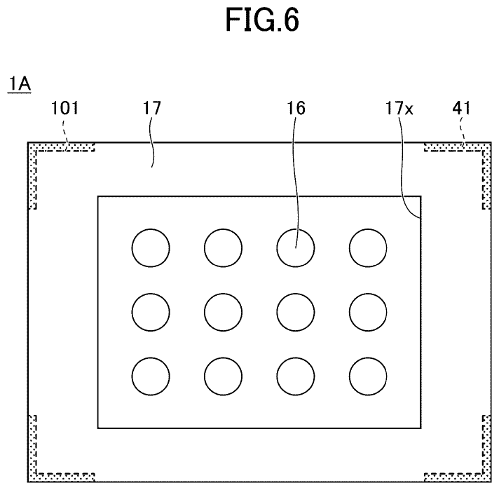

FIG. 6 is a plan view illustrating an example of an interconnect substrate according to a first variation of the first embodiment. An interconnect substrate 1A illustrated in FIG. 6 is configured such that first cut-outs 101 are separated from each other, and are each bent along the perimeter of a corresponding corner of the first surface 10a of the core layer 10. That is, the number of corners and the number of first cut-outs 101 are the same. Second cut-outs 102 may be, for example, provided at positions aligned with the first cut-outs 101 in plan view.

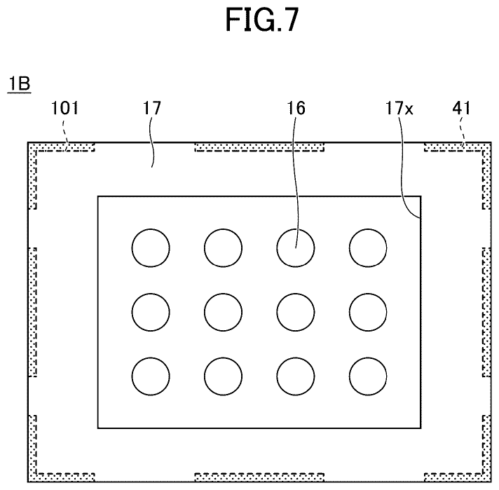

FIG. 7 is a plan view illustrating an example of an interconnect substrate according to the second variation of the first embodiment. An interconnect substrate 1B illustrated in FIG. 7 is configured such that first cut-outs 101 includes those provided at the same positions as in the interconnect substrate 1A and those provided between adjacent corners. In the interconnect substrate 1B, eight first cut-outs 101 spaced apart from each other are provided. The number of first cut-outs 101 spaced apart from each other may be greater. Second cut-outs 102 may be, for example, provided at positions aligned with the first cut-outs 101 in plan view.

As illustrated in FIGS. 6 and 7, it suffices for the first cut-outs 101 to include at least a portion bend along the perimeter of each corner of the first surface 10a. That is, one continuous first cut-out 101 that extends along the entire perimeter of the first surface 10a as in the first embodiment may not be necessary. Stress tends to concentrate on each corner of the first surface 10a and each corner of the second surface 10b when the temperature rises. Therefore, the first cut-outs 101 may be provided so as to include at least a portion bent along the perimeter of each corner of the first surface 10a, and the second cut-outs 102 may be provided so as to include at least a portion bent along the perimeter of each corner of the second surface 10b. Providing the first buffer layer 41 filling the first cut-outs 101 and the second buffer layer 42 filling the second cut-outs 102 serves to suppress internal fracture of the core layer 10 made of glass.

According to at least one embodiment, an interconnect substrate having a core layer made of glass is provided in which internal fractures in the glass are effectively suppressed.

Although the preferred embodiments have been described in detail, the present invention is not limited to these embodiments, and various modifications and substitutions may be made to the above-described embodiments without departing from the scope of the appended claims.

For example, the present invention is also effective for an interconnect substrate having an interconnect layer and an insulating layer only on one side of the glass core layer. In this case, a cut-out may be provided only on one side of the core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively include the subject matter set out in the following clauses.

Clause 1. A method of making an interconnect substrate, comprising:
providing a glass core layer having a plurality of interconnect regions for singulation into interconnect substrates and a cutting region along which cuts are to be made for the singulation;
forming, in one surface of the core layer, a first cut-out wider than the cutting region, the first cut-out extending along, and encompassing, the cutting region;
forming a first buffer layer filling the first cut-out;
providing a first insulating layer in each of the interconnect regions and the cutting region on the one surface of the core layer to form a multilayer structure, the first insulating layer covering the first buffer layer; and
cutting the multilayer structure along the cutting region to perform singulation,
wherein the first buffer layer has a lower elastic modulus than the first insulating layer.

Clause 2. The method of manufacturing an interconnect substrate according to clause 1, further comprising:
forming, in another surface of the core layer, a second cut-out wider than the cutting region, the second cut-out extending along, and encompassing, the cutting region;
forming a second buffer layer filling the second cut-out; and
providing a second insulating layer in each of the interconnect regions and the cutting region on the another surface of the core layer, the second insulating layer covering the second buffer layer,
wherein the cutting of the multilayer structure includes cutting, along the cutting region, the multilayer structure including the first insulating layer and the second insulating layer, and
wherein the second buffer layer has a lower elastic modulus than the second insulating layer.

What is claimed is:

1. An interconnect substrate comprising:
a core layer made of glass having one surface, another surface opposite the one surface, and a first cut-out located on an outer side of the one surface;
a first buffer layer filling the first cut-out; and
a first insulating layer disposed on the one surface of the core layer and covering the first buffer layer,
wherein the first buffer layer has a lower elastic modulus than the first insulating layer.

2. The interconnect substrate according to claim 1, wherein the first buffer layer has a higher thermal expansion coefficient than the first insulating layer.

3. The interconnect substrate according to claim 1, wherein an upper surface of the first buffer layer is flush with the one surface of the core layer, and the first insulating layer continuously covers the upper surface of the first buffer layer and the one surface of the core layer.

4. The interconnect substrate according to claim 1, wherein in plan view, the one surface of the core layer has a plurality of corners, and the first cut-out includes at least a portion bent along each of the corners of the one surface.

5. The interconnect substrate according to claim 1, further comprising
a second buffer layer filling a second cut-out made in the core layer and located on an outer side of the another surface; and
a second insulating layer disposed on the another side of the core layer and covering the second buffer layer,
wherein the second buffer layer has a lower elastic modulus than the second insulating layer.

6. The interconnect substrate according to claim 5, wherein the second buffer layer has a higher thermal expansion coefficient than the second insulating layer.

7. The interconnect substrate according to claim 5, wherein the lower surface of the second buffer layer is flush with the another surface of the core layer, and the second insulating layer continuously covers the lower surface of the second buffer layer and the another surface of the core layer.

8. The interconnect substrate according to claim 5, wherein in plan view, the another surface of the core layer has a plurality of corners, and the second cut-out includes at least a portion bent along each of the corners of the another surface.

9. The interconnect substrate according to claim 1, wherein the glass of the core layer is alkali-free glass, quartz glass, or borosilicate glass.

10. The interconnect substrate according to claim 1, wherein a thickness of the core layer is from 100 μm to 1000 μm, and
wherein the first cut-out has a width of 0.05 mm to 0.5 mm and a depth of 0.05 mm to 0.3 mm.

11. The interconnect substrate according to claim 4, wherein in the plan view, the first cut-out is formed in a closed-loop shape along a perimeter of the one surface of the core layer.

12. The interconnect substrate according to claim 4, wherein the first cut-out includes a plurality of sub-cut-outs separated from each other.

13. The interconnect substrate according to claim 1, wherein the first buffer layer is an insulating resin including an epoxy-based resin or a polyimide-based resin as a main component.

14. The interconnect substrate according to claim 1, wherein an elastic modulus of the first buffer layer is from 2 GPa to 8 GPa, and an elastic modulus of the first insulating layer is from 10 GPa to 15 GPa, and
wherein an elastic modulus of the core layer is from 70 GPa to 80 GPa.

15. The interconnect substrate according to claim 2, wherein a coefficient of thermal expansion of the first buffer layer is from 20 ppm/° C. to 110 ppm/° C., and a coefficient of thermal expansion of the first insulating layer is from 10 ppm/° C. to 20 ppm/° C., and
wherein a coefficient of thermal expansion of the core layer is from 3 ppm/° C. to 10 ppm/° C.
